(19) United States
(12) Patent Application Publication
(10) Pub. No.: US 2025/0279625 A1
(43) Pub. Date: Sep. 4, 2025

(54) HYBRID INTERGRATED LASER HAVING A SILICON PHOTONIC COUPLER MATCHED TO A PHOTONIC INTEGRATED CIRCUIT

(71) Applicant: Quintessent Inc., Goleta, CA (US)

(72) Inventors: Brian KOCH, Santa Barbara, CA (US); Michael DAVENPORT, Goleta, CA (US); Alan LIU, Santa Barbara, CA (US)

(21) Appl. No.: 19/070,071

(22) Filed: Mar. 4, 2025

Related U.S. Application Data
(60) Provisional application No. 63/561,116, filed on Mar. 4, 2024.
(60) Provisional application No. 63/676,968, filed on Jul. 30, 2024.

(51) Int. Cl. H01S 5/026; H01S 5/20

(52) U.S. Cl. CPC H01S 5/026; H01S 5/2054

(57) ABSTRACT

In accordance with a method, forming a semiconductor laser with a photonic integrated circuit (PIC) a laser die is provided that includes a semiconductor laser and a silicon-based photonic waveguide disposed on a silicon substrate. The silicon-based photonic waveguide is configured to receive optical energy generated by the semiconductor laser and provide the optical energy as output energy that is output from the laser die. The laser die is coupled with the PIC so that the optical energy output from the laser die is coupled to a photonic waveguide located on the PIC.

### CROSS REFERENCE TO RELATED APPLICATION

This application claims the benefit of U.S. Provisional Application No. 63/561,116, filed Mar. 4, 2024 entitled “HYBRID INTERGRATED LASER HAVING A SILICON PHOTONIC COUPLER MATCHED TO A PHOTONIC INTEGRATED CIRCUIT”, and U.S. Provisional Application No. 63/676,968, filed Jul. 30, 2024 entitled “HYBRID INTERGRATED LASER HAVING A SILICON PHOTONIC COUPLER MATCHED TO A PHOTONIC INTEGRATED CIRCUIT”. The contents of the provisional applications noted above are incorporated herein by reference.

### BACKGROUND

Integration of lasers, optical amplifiers, and/or other optical components that utilize III-V materials onto silicon or silicon nitride (or other indirect bandgap materials) can provide many benefits, but also comes with significant manufacturing challenges. A typical approach is to etch a large trench into a silicon photonic chip with silicon photonic waveguides at the edges of the trench, and carefully place a pre-fabricated laser into the trench with the laser waveguides aligned to the silicon photonic waveguide(s) (see references 1 and 2). As used herein, a silicon photonic waveguide refers to a silicon-based waveguide that is disposed on a silicon wafer or silicon on insulator wafer. Silicon-based waveguides are waveguides that employ silicon as one component, and include, for example, materials such as silicon, silicon nitride and silicon dioxide.

Typically, laser waveguides have fairly small optical mode field sizes relative to a silicon photonic spot size converter and the laser emission modes are often elliptical. A spot size converter refers to an optical element that converts an optical mode in one waveguide to a different optical mode in another waveguide, which is generally different in shape. An example of a spot size converter is a tapered waveguide in which the height and/or width of the waveguide is tapered to change the mode size. Another example of a spot size converter may transfer the optical mode from a first waveguide to a second waveguide that is adjacent, above and/or below the first waveguide.

FIGS. 1-4 illustrate the relative size of optical modes in waveguides of the type discussed above. FIGS. 1A and 1B show cross-sectional views through a typical laser, where the laser in FIG. 1B is wider than the laser in FIG. 1A. As the figures illustrate, the optical mode becomes highly elliptical as the laser width increases. FIGS. 2A-2C show cross-sections through three different silicon photonic waveguides, where the left-most and middle waveguides are silicon waveguides and the right-most waveguide is a SiN waveguide. The middle waveguide serves as a spot size converter for transferring an optical mode from the left-most waveguide to the right-most waveguide. FIGS. 3A-3C is similar to FIG. 2 except that in FIG. 3C the waveguide is located in a laser having a width that is wider than the laser in FIG. 3A. FIGS. 4A-4C are similar to FIGS. 3A-3C except that the spot size converter in FIG. 4 is a SiN waveguide instead of an Si waveguide as in FIG. 3. As FIG. 4 shows, the optical mode in the spot size converter is too large to be accommodated by typical lasers, resulting in excess loss of optical power when coupling between them. It should be noted that the drawings in FIGS. 1-4 as well as the figures that follow are not drawn to scale.

As FIGS. 1-4 illustrate, in some cases silicon photonic waveguides can be engineered to match the modes being transferred from laser waveguides, but typically the waveguide configuration is not ideal for minimizing waveguide to waveguide coupling losses when considering placement tolerances of the laser waveguide relative to the silicon photonic waveguide. Furthermore, a typical laser facet is susceptible to reliability issues stemming from surface interactions with the optical power on the III-V material (see Reference 3). These interactions result in defects that can propagate and cause a laser to fail. This is a particularly challenging problem for high power lasers but the problem is not limited to high powers.

The optical alignment challenges of placing a laser into a silicon photonic circuit trench can be dealt with by known techniques using high precision optical alignment equipment, but this comes with the disadvantage of requiring longer alignment times and careful calibration and maintenance of the equipment. Furthermore, the curing or other procedures performed after the initial alignment can impact the final position of the laser in the waveguide, so a solution with more tolerance would be highly desirable even if initial placement can be highly accurate. It has also proven difficult to make a laser optical mode that is sufficiently large to match to a large alignment tolerant waveguide, so even nominal coupling loss is not ideal. This results in inefficient use of the laser source since power is wasted in the optical link or optical system that uses the laser. While it is possible to make larger laser optical modes, this imposes limitations on the laser design that are often severe and result in non-ideal laser performance.

### SUMMARY

In one aspect, the present disclosure is directed toward a silicon photonic platform that integrates a semiconductor device such as a semiconductor laser with a silicon photonic waveguide located on photonic integrated circuit (PIC). In particular, the semiconductor device is integrated with a silicon-based photonic waveguide, which in turn is substantially identically matched to the silicon photonic waveguide used in the photonic integrated circuit into which the laser is placed. The semiconductor device may be formed on a die that includes the silicon-based photonic waveguide and, in addition, a mode converter that is used to couple light between the semiconductor device and the silicon photonic waveguide used in the photonic integrated circuit.

In one embodiment, a method of forming a semiconductor laser with a photonic integrated circuit (PIC) is presented. In accordance with the method, a laser die is provided that includes a semiconductor laser and a silicon-based photonic waveguide disposed on a silicon substrate. The silicon-based photonic waveguide is configured to receive optical energy generated by the semiconductor laser and provide the optical energy as output energy that is output from the laser die. The laser die is coupled with the PIC so that the optical energy output from the laser die is coupled to a photonic waveguide located on the PIC.

In some embodiments, a trench is formed in the PIC and the laser die is arranged in the trench so that the output optical energy output from the laser die is laterally coupled to the photonic waveguide located on the PIC.

In some embodiments the laser die is arranged in the trench such that the silicon substrate is located at a greater depth in the trench than the semiconductor laser.

In some embodiments, the laser die is arranged in the trench such that the semiconductor laser is located at a greater depth in the trench than the silicon substrate.

In some embodiments, the silicon-based photonic waveguide is configured to be optically mode matched to the photonic waveguide located on the PIC.

In some embodiments, the laser die is arranged on the PIC so that the output optical energy that is output from the laser die is vertically coupled to the photonic waveguide located on the PIC.

In some embodiments the laser die further includes a silicon waveguide disposed on the silicon substrate. The silicon waveguide is configured to directly receive the optical energy from the semiconductor laser and couple the optical energy to the photonic waveguide located on the PIC.

The method in accordance with the present disclosure offers a number of advantages. For example, the method allows exact or near exact matching of the laser die's output waveguide (e.g., a silicon-based photonic waveguide) to the photonic waveguide on the PIC, which enables very low optical coupling losses if other factors are well designed. Because silicon-based photonic waveguides can be engineered to have very large optical mode sizes similar to optical fibers, this approach also enables large optical modes to be coupled, resulting in low optical coupling loss and higher than typical alignment tolerances. This approach has the additional reliability advantage of avoiding a III-V material facet.

Another advantage is that the method enables a more straightforward way to integrate high quality semiconductor devices such as lasers with any foundry that can manufacture typical silicon photonic waveguides and trenches in which semiconductor devices can be placed, thereby making the overall fabrication process more cost efficient. Other advantages and features will be discussed below.

This Summary is provided to introduce a selection of concepts in a simplified form that are further described below in the Detailed Description. This Summary is not intended to identify key features or essential features of the claimed subject matter, nor is it intended to be used as an aid in determining the scope of the claimed subject matter. Furthermore, the claimed subject matter is not limited to implementations that solve any or all disadvantages noted in any part of this disclosure.

### BRIEF DESCRIPTION OF THE DRAWINGS

FIGS. 1A and 1B show cross-sectional views through a typical laser, where the laser in FIG. 1B is wider than the laser in FIG. 1A.

FIGS. 2A, 2B and 2C show cross-sections through three different silicon photonic waveguides, where the left-most and middle waveguides are silicon waveguides and the right-most waveguide is a SiN waveguide.

FIGS. 3A, 3B and 3C are similar to FIG. 2 except that in FIG. 3C the waveguide is located in a laser having a width that is wider than the laser in FIG. 3A.

FIGS. 4A, 4B and 4C are similar to FIGS. 3A-3C except that the spot size converter in FIG. 4B is a SiN waveguide instead of an Si waveguide as in FIG. 3B.

FIG. 5A shows the optical mode emitted at the laser die interface in accordance with the present disclosure and FIG. 5B shows substantially the same optical mode being coupled into a silicon photonic waveguide on a photonic integrated circuit.

FIG. 6A shows a top view of one example of an optical system in accordance with the present disclosure.

FIG. 6B shows an expanded side view of the laser, the silicon waveguide, the silicon-based photonic waveguide and the PIC waveguide of the optical system shown in FIG. 6A.

FIG. 6C shows a cross-sectional view of the optical system shown in FIG. 6A taken though line a-a.

FIGS. 7A, 7B, 7C and 7D show cross-sectional views of the optical system taken through lines b-b though e-e, respectively, in FIG. 6A.

FIG. 8 shows one example of the active material stack of the semiconductor laser incorporated in the optical system in accordance with the present disclosure.

FIG. 9 shows a top view of one example of the optical mode converter incorporated on the laser die 120 of the optical system in accordance with the present disclosure.

FIGS. 10A and 10B show a top view and a cross-sectional view, respectively, of one alternative embodiment of the optical system in accordance with the present disclosure.

FIGS. 11A, 11B, 11C and 11D show cross-sectional views of the optical system shown in FIG. 10A taken through lines b-b through e-e, respectively.

FIG. 12A shows a top view of a semiconductor optical amplifier (SOA) die disposed in a PIC trench for coupling light between PIC waveguides having facets located on opposite sides of the trench.

FIG. 12B shows a top view of a SOA die disposed in a PIC trench for coupling light between PIC waveguides having facets located on the same side of the trench.

FIG. 13A shows a top view of another example of a SOA die disposed in a PIC trench for coupling light between PIC waveguides having facets located on the same side of the trench using a bent silicon photonic waveguide that is integrated of the SOA die.

FIG. 13B shows a top view of yet another example of a SOA die disposed in a PIC trench for coupling light between PIC waveguides having facets located on the same side of the trench using a bent silicon photonic waveguide that is integrated of the SOA die.

FIG. 14A shows a top view of another embodiment of an optical system in accordance with the present disclosure in which a semiconductor laser is integrated with a silicon photonic waveguide without the use of a trench.

FIG. 14B shows a cross-sectional view of the optical system in FIG. 14A taken along line a-a.

FIGS. 15A, 15B, 15C and 15D show cross-sectional views of the optical system in FIG. 14A taken along lines b-b through e-e, respectively.

### DETAILED DESCRIPTION

For the purposes of this Specification, including the appended claims, the terms “lateral” and “vertical” as used are meant to be relative to the major surfaces of a substrate on which an integrated-optics system resides, where the term lateral refers to directions that are parallel to the major surfaces and the term vertical refers to directions that are normal to the major surfaces. In similar fashion, the term “lower” means more proximate to the substrate and the term “higher” means more distal from the substrate.

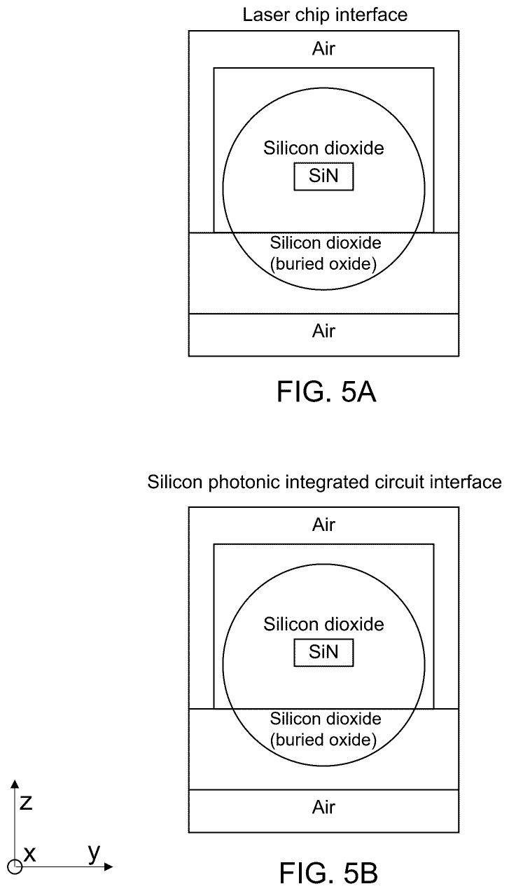

In one aspect, the present disclosure provides a semiconductor laser that is heterogeneously integrated with a silicon-based photonic waveguide, which in turn is substantially identically matched to the PIC waveguide used in the photonic integrated circuit into which the laser is placed. This is shown in FIGS. 5A and 5B, which shows the optical mode emitted at the laser die optical output interface and FIG. 5B shows substantially the same optical mode being coupled into a silicon photonic waveguide on a photonic integrated circuit.

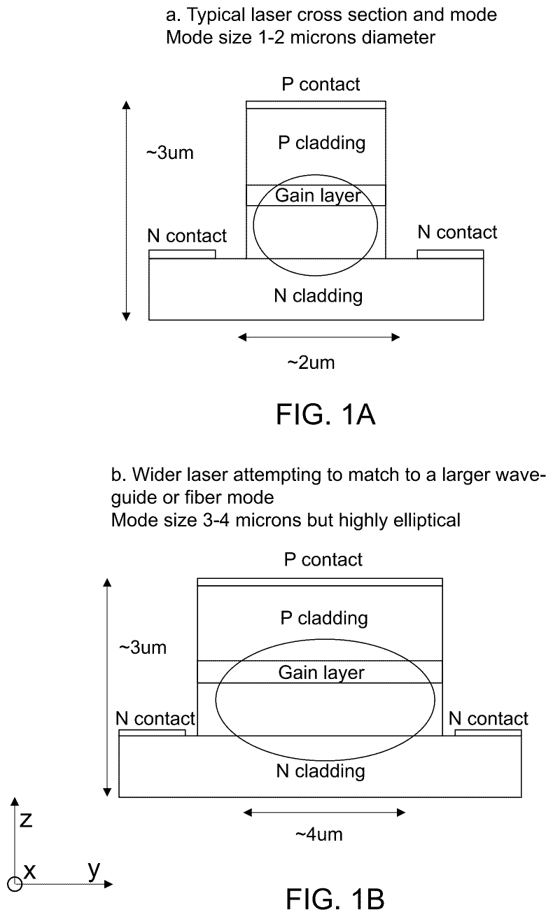

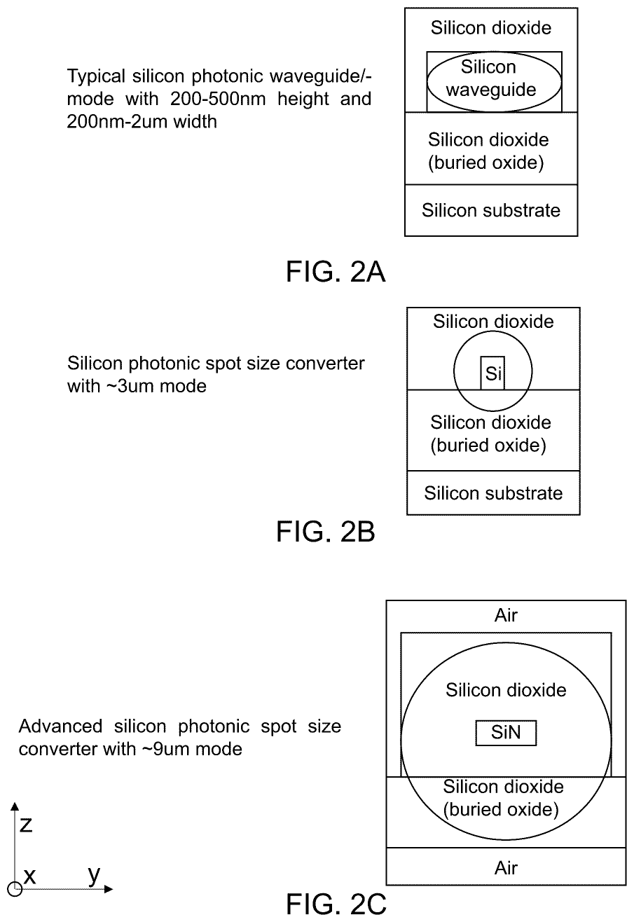

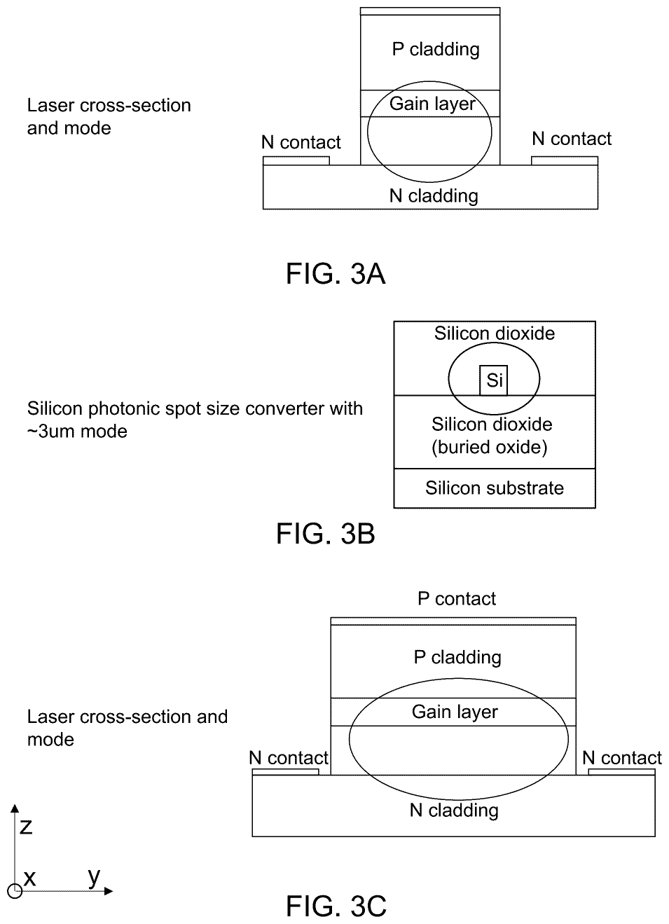

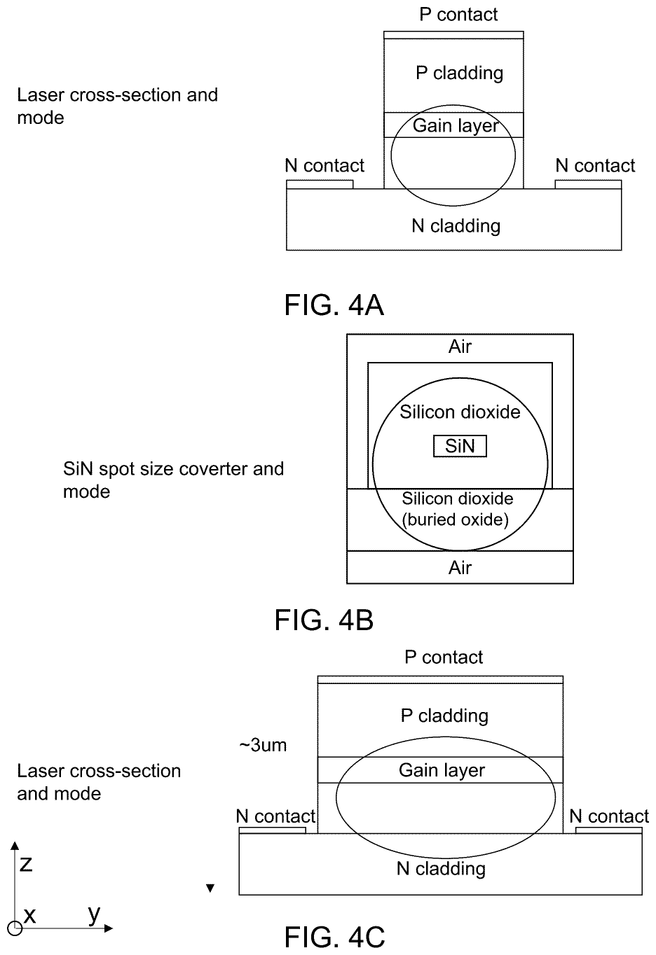

One example of a method of forming a semiconductor laser that is heterogeneously integrated with a silicon-based photonic waveguide is shown in U.S. Pat. No. 11,131,806 to Koch et. al (“Koch”), which is hereby incorporated by reference in its entirety. This application shows a III-V laser waveguide coupling into a passive silicon waveguide. In this way an optical mode can be transferred from the laser waveguide to a silicon waveguide. For instance, FIGS. 1 and 2 of Koch show a laser or other optically active device 110 that includes an active material stack 210 and a coupling waveguide 112. An optical mode from laser 110 is optically coupled to a PIC waveguide, which in the example of FIG. 1 of Koch is a silicon waveguide 116.

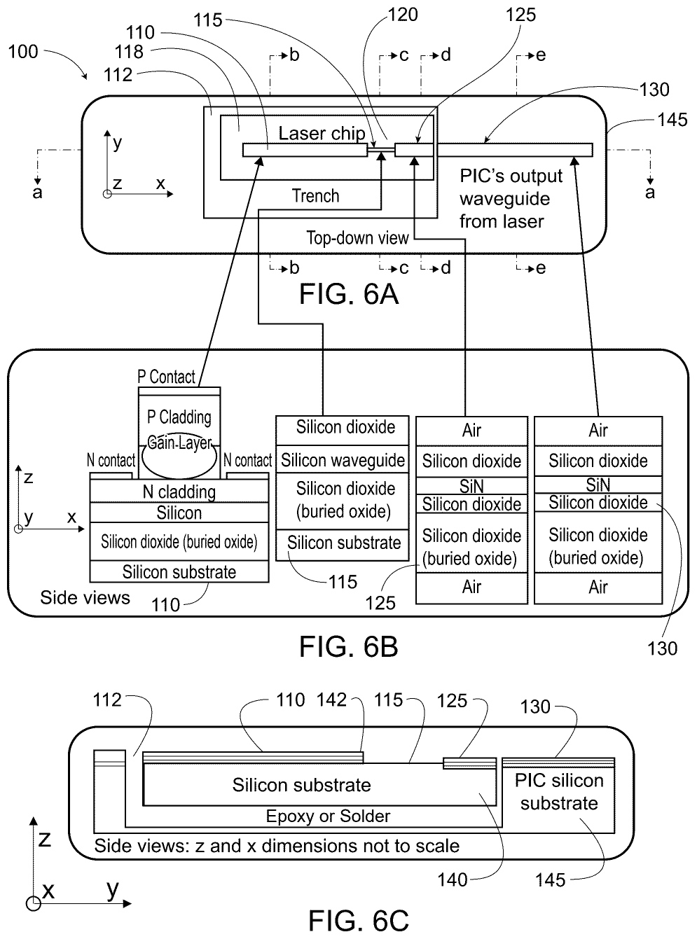

In the present disclosure, a laser that is heterogeneously integrated with a PIC waveguide such as illustratively shown in Koch is further integrated with a spot size or mode converter to form a nearly ideal laser source that, in some embodiments, can be placed in a silicon PIC trench. One example of such an optical system in accordance with the present disclosure is depicted in FIGS. 6-9, which are described below. Moreover, it should be noted that in FIG. 6 and the figures that follow, like elements are denoted by like reference numerals.

FIG. 6A shows a top view of one example of an optical system 100 that includes a semiconductor laser chip or die 118 that is heterogeneously integrated with a silicon waveguide 115, which is in turn coupled to a differently sized silicon-based photonic waveguide 125 via a mode converter 120. The laser 110 is defined by an active material stack, which, along with the silicon waveguide 115, the spot size converter 120 and silicon-based photonic waveguide 125, are integrated on the laser die 118. The resulting laser die 118 is placed in a trench 112 located in a silicon PIC substrate 145 as shown. The optical mode output from the laser 110 by the silicon-based photonic waveguide 125 is provided to a PIC waveguide 130 on the PIC substrate 145. FIG. 6B shows an expanded side view of the active material stack of laser 110, the silicon waveguide 115, the silicon-based photonic waveguide 125 and the PIC waveguide 130.

FIG. 6C shows a cross-sectional view of the optical system 100 shown in FIG. 6A taken though line a-a. As shown, the laser die 118 includes an active material stack 142 that is formed on the silicon substrate 140 of the laser die 118. The active material stack 142 forms the active components of the laser 110. The laser die 118 may be secured in the trench using any suitable means, including, for example, epoxy or solder, or, in some cases, mechanical latches or fixtures.

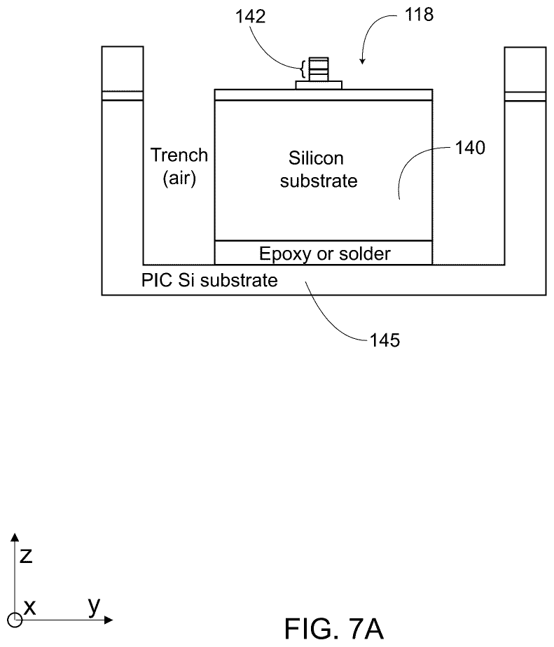

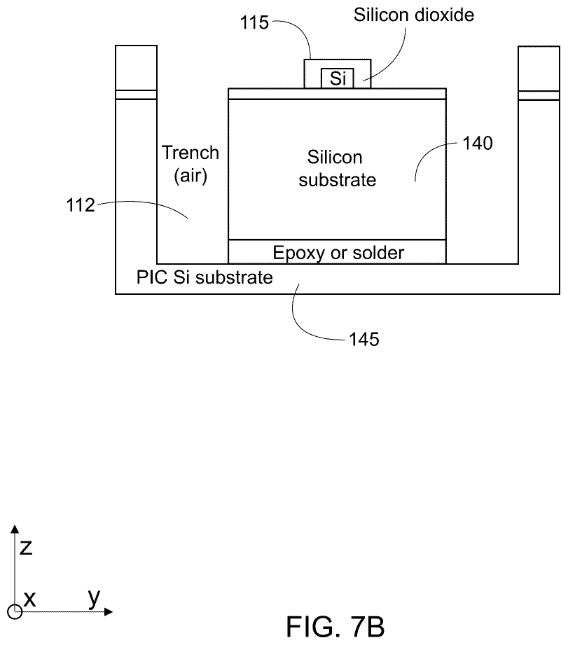

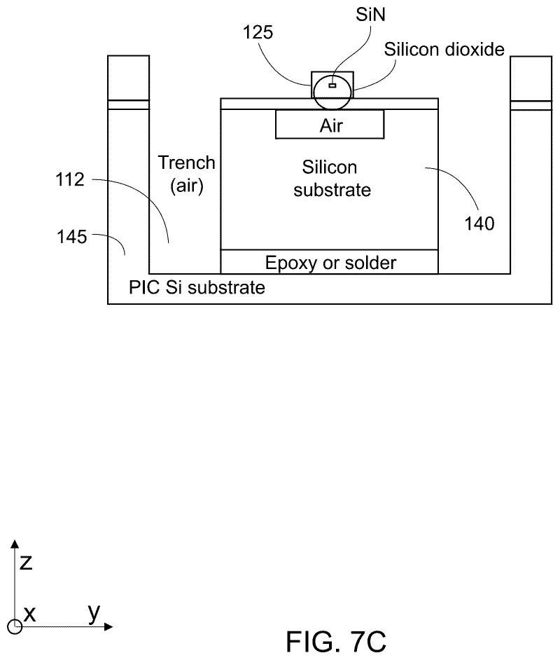

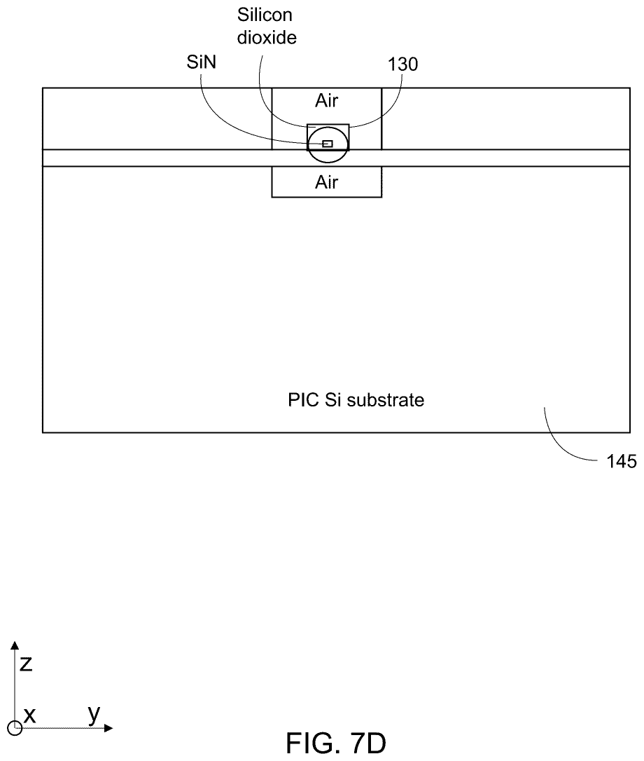

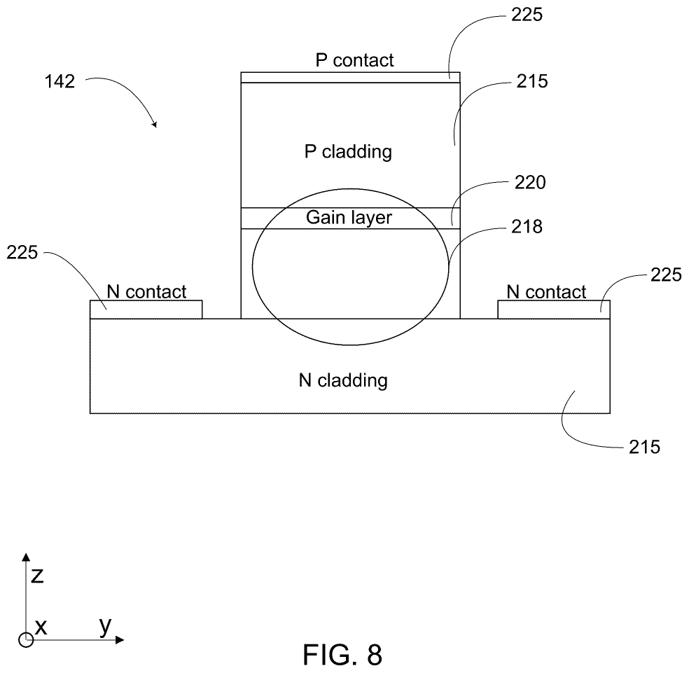

FIGS. 7A-7D show cross-sectional views of optical system 100 taken through lines b-b though e-e, respectively, in FIG. 6A. FIG. 7A shows a cross-sectional view of laser die 118 taken through lines b-b. As shown, the laser 118 includes the active material stack 142 formed on the silicon substrate 140 of the laser die 118. One example of the active material stack 142 is shown in FIG. 8. As shown, active-material stack 142 includes the constituent layers of laser 110, including cladding layers 215, waveguide 218, and gain layer 220, as well as electrical contacts 225.

FIG. 7B shows a cross-sectional view of silicon photonic integrated waveguide 115 taken through lines c-c. As shown, the silicon waveguide 115 is formed on the silicon substrate 140 of the laser die 118. FIG. 7C shows a cross-sectional view of silicon-based photonic waveguide 125 taken through lines d-d. FIG. 7D shows a cross-sectional view of PIC waveguide 130 taken through lines e-e.

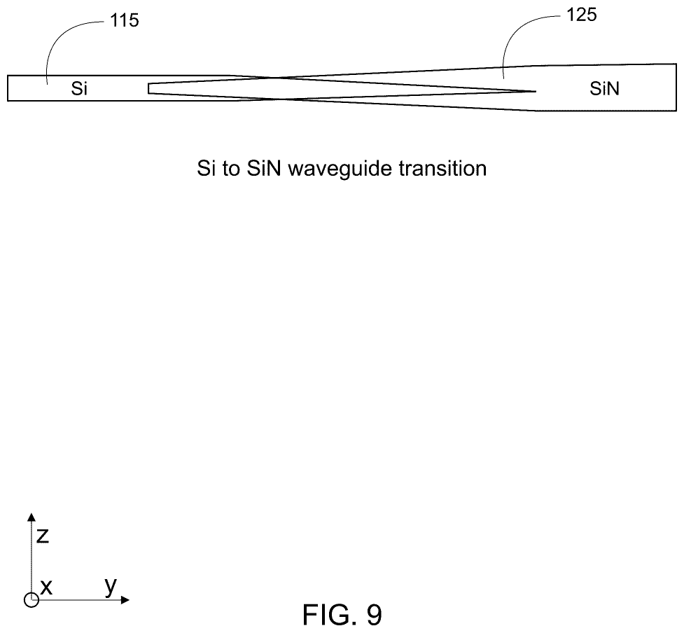

FIG. 9 shows a top view of one example of the optical mode converter 120. In the illustrative example the optical mode converter 120 is a tapered portion of the Si-based photonic waveguide 125, which in this particular case is a SiN waveguide. The tapered portion of the Si-based photonic waveguide 125 couples light from the Si waveguide 115 to a larger optical mode in the silicon-based photonic waveguide 125. One example of such a tapered SiN waveguide is shown in W. D. Sacher et al., “Monolithically Integrated Multilayer Silicon Nitride-on-Silicon Waveguide Platforms for 3-D Photonic Circuits and Devices,” in Proceedings of the IEEE, vol. 106, no. 12, pp. 2232-2245 December 2018, doi: 10.1109/JPROC.2018.2860994, which is hereby incorporated by reference in its entirety. In one particular embodiment, the tapered SiN waveguide 125 may be a dilute silicon nitride waveguide with a 100-300 micron SiN thickness surrounded by silicon dioxide, or even further coupled to an air clad waveguide to further expand the mode.

In the example shown in FIGS. 6-9, the silicon-based photonic waveguide 125 and the PIC waveguide 130 are illustrated as being SiN waveguides, but more generally may be any suitable type of silicon photonic waveguides. The techniques described herein also may be used integrate other III-V devices such as high-speed optical modulators and/or photodetectors.

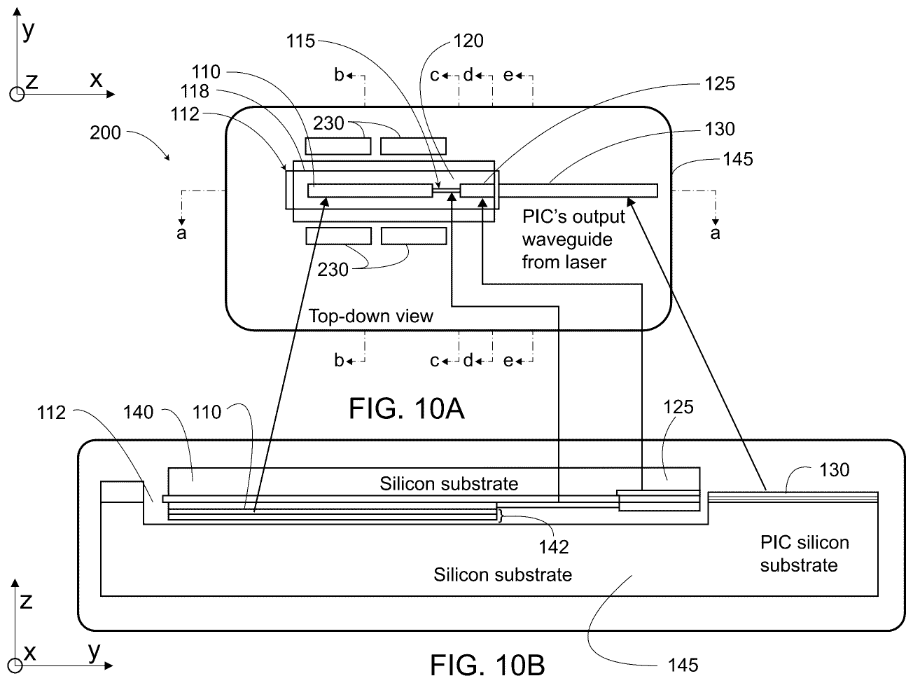

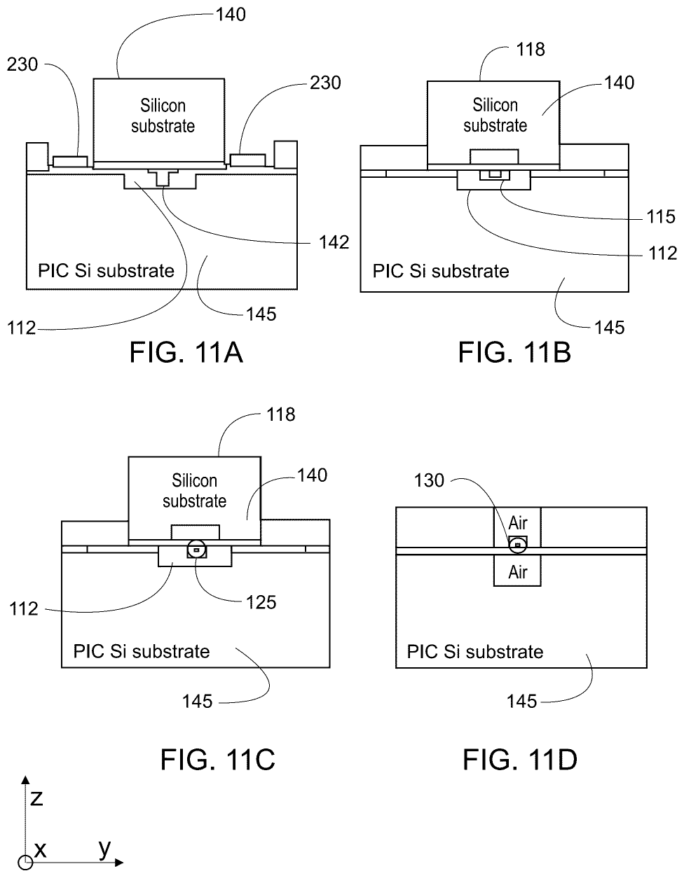

FIGS. 10A and 10B show one alternative embodiment of the optical system shown in FIGS. 6-9. In this embodiment the laser die 118 is inverted when placed in the trench 112 so that the active material stack 142 is located at a greater depth in the trench 112 than the laser die substrate 140. FIG. 10A shows a top view of the optical system 200 and FIG. 10B shows a cross-section view taken along line a-a in FIG. 10A. FIGS. 11A-11D show cross-sectional views of optical system 200 taken through lines b-b through e-e, respectively. FIGS. 11A-11D are analogous to the cross-sectional views shown in FIGS. 7A-7D, which show cross-sectional views of the previously described embodiment in which the laser die 118 in not inverted. For purposes of clarity, the laser die substrate 140 is illustrated as being transparent in the top view of optical system 200, thereby allowing the laser 110, photonic integrated waveguide 115 and silicon photonic waveguide 125 to be depicted. As seen in FIGS. 10A and 11A, the electrical pads 230 for the laser 110 may be located on the PIC substrate 145 adjacent to the trench 112. Electrical traces may formed on both the PIC substrate 145 and laser die 118 to electrically couple the laser 110 to the electrical pads 230.

While the examples described above illustrate the integration of a semiconductor laser with a silicon-based photonic waveguide, more generally the techniques described herein may be used to integrate other optically active devices with a silicon-based photonic waveguide. Examples of such optically active devices include, without limitation, integrated gain blocks and integrated semiconductor optical amplifiers (SOAs). Moreover, while the integrated laser has been described as being fabricated in accordance with the method shown in the Koch reference described above, more generally the integrated laser or other optically active device may be integrated on silicon, silicon nitride or silicon dioxide by, for example, wafer bonding or growth processes. In some embodiments the laser die may have special optical or mechanical alignment features to enable the precise placement of the laser die into the silicon photonic circuit. These features or other mechanical features may also hold the laser in place and/or allow the laser to be released from its position when desired. The facet(s) of the lasers may be etched or, alternatively, they may have been diced and polished or simply diced.

The silicon photonic integrated circuit in which the laser described herein is to be incorporated may be fabricated in a conventional manner, except that in some embodiments it may be is provided with one or more features to enable the laser to be placed into the trench. These features may include:
1. A trench opening at least as large as the laser, but not necessarily as deep as the laser is high.
2. A silicon photonic waveguide (e.g., waveguide 130 in FIG. 6) that extends to the edge of the trench in a particular location, including at a specific height above the bottom of the trench. This waveguide is designed to support substantially the same optical mode field as the laser's output waveguide e.g., output waveguide 125 in FIG. 6). Moreover, this waveguide may be fabricated using the same manufacturing process and same dimensions as the laser's output waveguide. The facet of the waveguide exposed to the trench may be etched to form a clean waveguide edge, possibly at a specific angle matched to the angle of the laser emission.
3. An optical and/or mechanical alignment feature may be provided to assist with placement of the laser die into the trench. In some cases, the laser die may be actively aligned, either by:
a. biasing the laser and measuring light coupled into the silicon photonic PIC using a detector on the PIC or a loopback waveguide that connects back to a detector on the laser die through the silicon photonic PIC via another edge coupling between the PIC and laser die; or
b. sending light into the PIC and routing that light into the laser die and back out of the laser die using a passive waveguide on the laser die, and then back to a photodetector located on the PIC or external to the PIC (in which case the light is coupled back out of the PIC to an external detector).
4. The trench depth may be chosen so that the height of the waveguide on the silicon photonic circuit will match the height of the laser output waveguide. This may require accounting for any solder or curing material that needs to be placed at the bottom of the laser trench. The laser and silicon photonic circuit may be co-designed such that layers in the material stacks can be precisely etched away, either selectively or non-selectively, to enable this precise height alignment. For example, the silicon photonic circuit trench may be designed to etch to the bottom of the buried oxide layer, with the buried oxide layer designed to have a specific thickness to match the laser thickness, resulting in precise height alignment of the laser and silicon photonic circuit waveguides. The laser may have similar features for matching the trench such as having the same height as the silicon nitride waveguide above the buried oxide layer. The laser also may have its silicon substrate removed, leaving a specific buried oxide thickness with a height optimized to fit into the silicon photonic circuit trench. In some cases the laser die and/or the silicon photonic PIC trench may have pedestals specifically designed to be at certain heights to enable waveguide alignment.

The laser and silicon photonic circuit waveguides may be anti-reflection coated, and/or they may have special material deposited between them after placement to assist with optical coupling. The region between the laser die and silicon photonic circuit may have a photonic wire bond formed after placement of the laser die.

The laser generally has both p and n contacts on its top surface, which can be wire bonded. Alternatively, the laser can be post-processed to form metal layers that route from pads on the PIC to the lasers. These pads may be routed from solder bump locations or through silicon via locations. Alternatively, the laser may have one or both p and n contacts on the bottom surface of the laser (and/or the laser may be placed top down into the trench), in which case the trench would contain pre-fabricated electrical contact points that route to elsewhere for biasing of the laser. These could be routed to the top surface of the silicon photonic circuit or the bottom surface of the silicon photonic circuit.

In some embodiments, rather than placing the laser die into a trench formed in the silicon photonic circuit, the laser die may be placed next to a physical edge of the silicon photonic circuit. In these embodiments the base platform holding the PIC and the laser die may be flat if the laser and PIC dies have the same or similar thicknesses. Alternatively, the base platform may incorporate steps or extra spacer materials if the laser die and the PIC die have different thicknesses.

In some embodiments the laser die and the PIC die may utilize matched vertical couplers instead of edge couplers. These vertical couplers could be grating couplers, turning mirrors, or other vertical coupling features formed in the silicon photonic waveguides, which produce nominally the same mode on both the laser die and the PIC die, and may have the identical structure for optimized coupling. In this case the laser die would be placed on top of (or possibly below) the PIC die and the light coupling occurs vertically between the two dies.

The method of integrating a semiconductor laser with a silicon photonic waveguide as described herein has a number of advantages over conventional techniques. For instance, the present method advantageously allows exact or near exact matching of the laser die's output waveguide (e.g., silicon-based photonic waveguide 125) to the PIC waveguide (e.g., waveguide 130) on the PIC, which enables very low optical coupling losses if other factors are well designed. Because silicon-based photonic waveguides can be engineered to have very large optical mode sizes similar to optical fibers, this approach also enables large optical modes to be coupled, resulting in low optical coupling loss and higher than typical alignment tolerances. This approach has the additional reliability advantage of avoiding a III-V material facet.

Further, packaging stress related to the thermal coefficient of expansion mismatch between silicon and compound semiconductor material is substantially reduced due to the much smaller mass of compound semiconductor material that is needed (e.g., a few microns thick of compound semiconductor material) compared to traditional methods of hybrid integration, which utilize compound semiconductor dies hundreds of microns thick.

The fabrication of lasers on a silicon photonic platform as described herein may offer additional advantages relative to III-V lasers, such as advantages resulting from the availability of better tools in silicon foundries. These advantages may include better yield, better lithography capabilities leading to novel device features, as well as better processing resulting in improved reliability. While it may be more desirable ultimately to integrate the laser on silicon photonics with the rest of the silicon photonic PIC, this may not be possible for silicon photonic PICs fabricated at all foundries. The method described herein enables a more straightforward way to integrate high quality silicon photonic lasers (or other devices) with any foundry that can manufacture typical silicon photonic waveguides and trenches in which lasers (or other devices) can be placed. This approach may also be more cost effective for several reasons. It can allow more expensive processes to yield more of their expensive components (i.e. lasers) per unit area and then be placed into a PIC that used a less expensive process. This approach can also separate the yields of components from PICs, allow for separate processes that may each require fewer steps, and parallelize the manufacturing process to enable a faster time from start to final product.

As another advantage, the placement of a laser on a silicon platform may make the packaging/assembly process more straightforward compared to a laser on a III-V substrate. For example, silicon is less fragile and less prone to breakage due to handling and may have undergo reduced mechanical deformations when placed or handled.

The techniques described herein may be combined with standard methods of alignment such as the use of optical or mechanical features to assist with the placement of the laser die into the silicon photonic circuit trench. The output of the laser may be an etched facet on the wafer, which can allow for wafer level testing of the laser output.

These techniques also may be compatible with transfer printing, whereby the lasers are formed on a silicon substrate, and special layers/features are implemented on the lasers such that they can be picked up from their wafer and dropped into the silicon photonic circuit wafer via transfer printing. This or other methods may allow multiple lasers or arrays of lasers/SOAs/modulators/photodetectors to be placed simultaneously onto the silicon photonic circuit wafer.

The silicon photonic circuit and laser die also may be co-designed such that multiple lasers and/or amplifiers and/or other III-V based components are located on the same die that is placed in the trench on the silicon photonic circuit. This may allow for fewer placements, faster throughput, better yield, and/or more efficient use of space on either or both wafers.

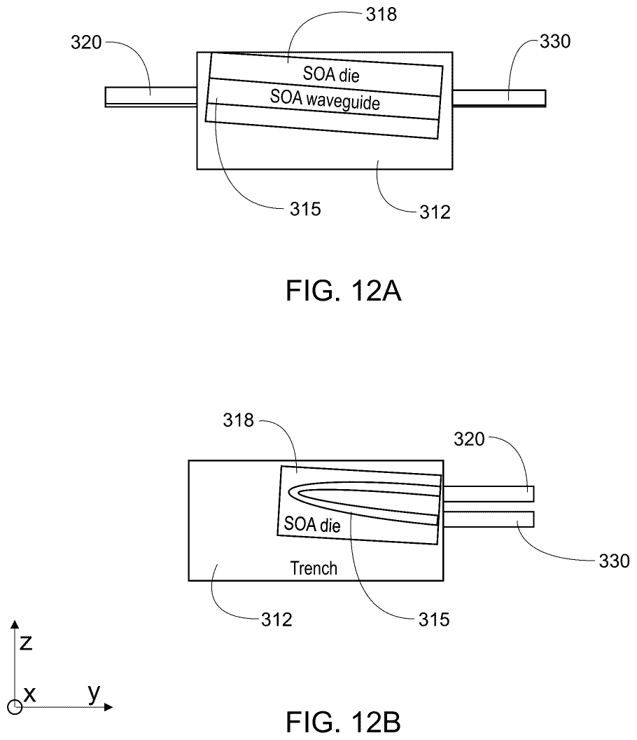

When integrating a SOA with a silicon photonic waveguide, the provision of SOA(s) on silicon that are placed into a trench has an additional advantage when integrated using the techniques described herein compared to conventional techniques. When placing an SOA (or any other component with an optical input and output or multiple optical ports of any kind) into a trench and aligning the waveguides, both the input and output waveguide must be aligned and the die and trench dimensions must be very carefully matched, which can cause additional difficulties relating to design and placement. For example, if both edges of the die must be very close to the edge of the trench in order to maximize optical coupling efficiency, then dimensions must be precisely matched and any material used to bond the die into the trench must not squeeze out in the narrow gap. This is illustrated in FIG. 12A, which shows a top view of an SOA die 318 in a trench 312. The SOA die 318 is to optically couple light between input PIC waveguide 320 and output PIC waveguide 330 via SOA waveguide 315. To obtain optimal alignment, the rotation of the SOA die 318 within the trench 312 needs to be almost perfect. To obtain optimal coupling, the trench 312 width needs to be almost exactly the same as the length of the SOA die 318. Furthermore, the precise angular requirement that is needed so that the waveguide ends on both sides of the SOA die 318 align to the waveguide ends on both sides of the trench 312 is much more challenging than the angular requirement that is needed when only optimizing one side.

One approach to overcome this problem is to provide a bend in the SOA waveguide 315 of the SOA die 318 so that both the input and output facets are on the same side of the die. This approach is illustrated in FIG. 12B, which shows the PIC waveguides 320 and 330 being located on the same side of the trench 312. As shown, the SOA waveguide 315 has a U-bend so that its input and output are located on the same facet. However, bending a III-V waveguide, particularly an active III-V waveguide, can be challenging because of the waveguide etches that are used (some are crystallographic, or other roughness is likely to occur), because gain may not be the same in different dimensions, and because making tight bends in III-V laser and amplifier waveguides is often difficult due to the weak confinement of the active waveguide, resulting in higher loss or much larger die compared to a bend in a silicon photonic waveguide.

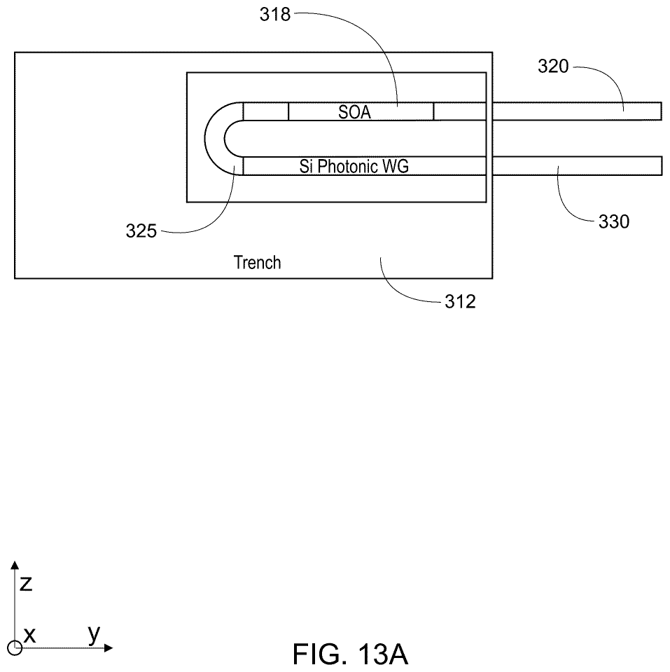

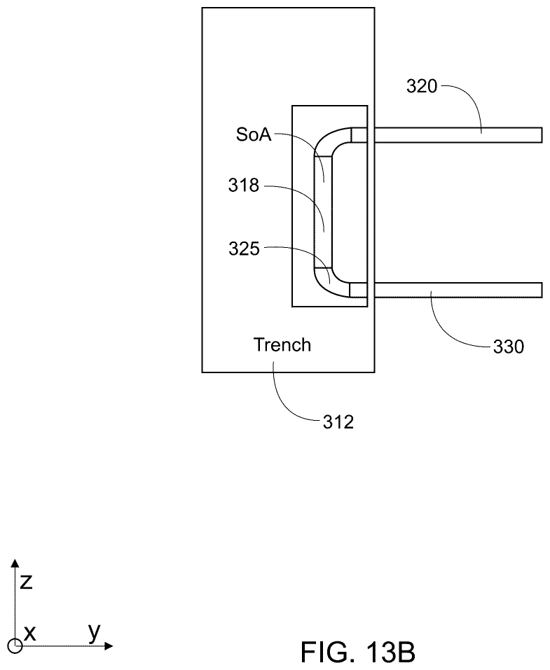

To address this problem, the silicon-based photonic waveguide formed with the SOA on the SOA die 318 may be bent as shown in FIG. 13A. Therefore, by forming an SOA die 118 with a silicon-based photonic waveguide 325, it is possible to have a compact, low loss bend integrated with the SOA, enabling the SOA to have its input and output on the same side and in close proximity to each other. Because the silicon-base photonic waveguides can be easily bent and routed in small areas, this approach also allows for more flexible configurations of the SOA die dimensions and orientation of the SOA die 318 in the trench on the PIC. For instance, FIG. 13B shows an arrangement in which the SOA die 318 has a different orientation and dimensions from that shown in FIG. 13A.

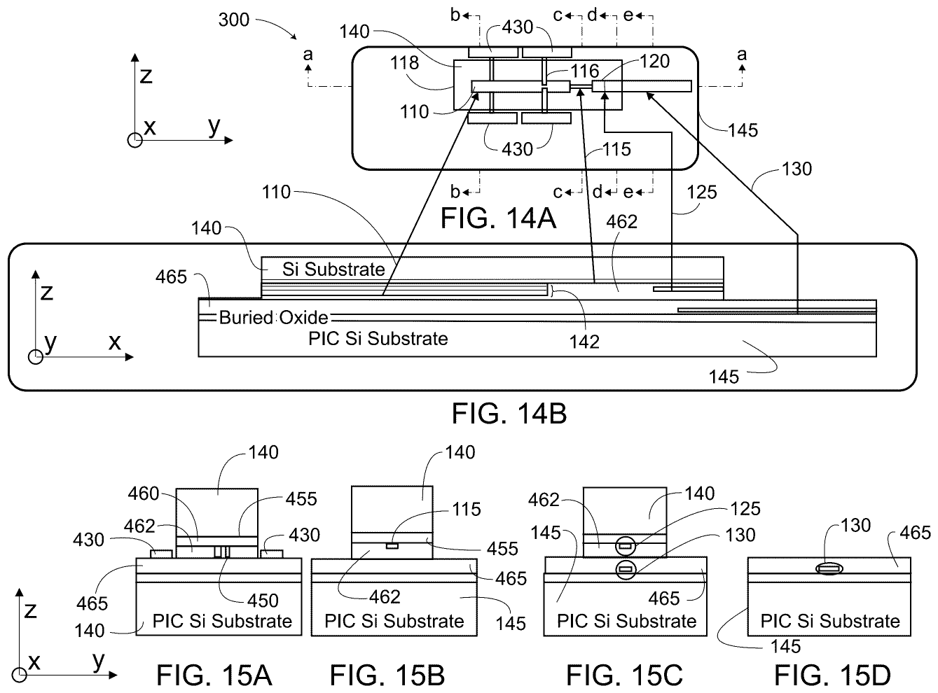

FIG. 14 shows another embodiment of an optical system in which a semiconductor laser integrated with a silicon photonic waveguide that does not require a trench. In this embodiment the laser die is placed directly on top of the silicon photonic circuit. A PIC waveguide on the silicon photonic circuit is designed to match with and couple light from the laser die's output waveguide when the two chips are in close proximity. This coupling can be achieved using, for example, a directional coupler, whereby the light couples between the waveguides over a specific carefully controlled distance along the direction of light propagation. Alternatively, the coupling may be achieved using an adiabatic type of taper between the laser die and the silicon photonic die. The vertical coupling may include contra-directional couplers to assist with the coupling.

One example of this embodiment of a semiconductor laser integrated with a silicon photonic waveguide that avoids the need for a trench is shown in FIGS. 14 and 15. As shown, the active material stack 142 of laser 110 may be placed directly over the PIC waveguide 130. FIG. 14A shows a top view of the PIC 300 and FIG. 14B shows a cross-sectional view taken along line a-a in FIG. 14A. FIGS. 15A-15D show cross-sectional views of PIC 300 taken along lines b-b through e-e, respectively. For purposes of clarity, the laser die substrate 140 is illustrated in the top view of FIG. 14A as being transparent, thereby allowing the laser 110, photonic integrated waveguide 115 and silicon photonic waveguide 125 to be depicted. In this embodiment the laser die 118 is inverted as shown in the embodiment of FIG. 11, but in this case the active material stack 142 is placed directly on the surface of the PIC 300, which may be a dielectric layer 465. As seen in FIG. 15A, the active material stack 142 may be sealed in a dielectric cladding layer 462, which may also contain vias 450 for connecting the active material stack 142 through to the PIC surface. As seen in FIGS. 14A and 15A, the electrical pads 430 for the laser 110 may be located on the PIC substrate 145 adjacent to the trench 112. Electrical traces may be formed on both the PIC substrate 145 and laser die 118 to electrically couple the laser 110 to the electrical pads 430.

This vertical coupling arrangement may be designed to have a specific gap between the two dies such that the coupling is optimized between the two waveguides. This gap may be controlled by machinery and maintained using adhesive or epoxy, and/or by the use of mechanical elements having a specific size, such as silica microspheres embedded in the adhesive/epoxy used to join the dies. Solder may be used in addition to, or instead of adhesive and epoxy, possibly to connect electrical traces or ports on the laser die to the PIC die. The adhesive and/or solder may be placed in specific locations on the laser die and/or PIC die before the two are joined. For example, solder may be placed on the laser or PIC electrical pads before placement, while adhesive or epoxy may be placed above or to the sides of the optical waveguides on the same or opposing laser or PIC die. Solder or other heat sinking materials may be used in the region that is in close contact with the laser gain region, either on the PIC die material stack or in the area between the PIC die and the laser die.

If the gap between the laser or PIC die is not perfectly controlled, an additional lateral offset between the laser die and silicon photonic die may be found during alignment to optimize the coupling.

In some embodiments, the laser die and PIC die may be directly bonded with dielectrics in direct contact, and/or with metals in direct contact.

In some embodiments there may be vertical coupling between the dies using mirrors or vertical grating couplers, which are designed to be ideally or nearly ideally matched to each other for optimal coupling by using the same or similar materials on both the laser die and silicon photonic die.

In some embodiments there may be additional mechanical features that allow the laser to be removed and later re-coupled to the photonic integrated circuit or replaced with a similar laser that is re-coupled to the photonic integrated circuit.

For the purposes of this Specification, including the appended claims, the terms “lateral” and “vertical” as used are meant to be relative to the major surfaces of a substrate on which an integrated-optics system resides, where the term lateral refers to directions that are parallel to the major surfaces and the term vertical refers to directions that are normal to the major surfaces. In similar fashion, the term “lower” means more proximate to the substrate and the term “higher” means more distal from the substrate.

It is to be understood that the present disclosure teaches only examples of embodiment in accordance with the present disclosures and that many variations of these embodiments can easily be devised by those skilled in the art after reading this disclosure and that the scope of the present invention is to be determined by the following claims.

1. A method of forming a semiconductor laser with a photonic integrated circuit (PIC), comprising:
providing a laser die that includes a semiconductor laser and a silicon-based photonic waveguide disposed on a silicon substrate, the silicon-based photonic waveguide being configured to receive optical energy generated by the semiconductor laser and provide the optical energy as output energy that is output from the laser die; and
coupling the laser die with the PIC so that the optical energy output from the laser die is coupled to a photonic waveguide located on the PIC.

2. The method of claim 1, further comprising:
forming a trench in the PIC;
arranging the laser die in the trench so that the output optical energy output from the laser die is laterally coupled to the photonic waveguide located on the PIC.

3. The method of claim 2, wherein the laser die is arranged in the trench such that the silicon substrate is located at a greater depth in the trench than the semiconductor laser.

4. The method of claim 2, wherein the laser die is arranged in the trench such that the semiconductor laser is located at a greater depth in the trench than the silicon substrate.

5. The method of claim 1, wherein the silicon-based photonic waveguide is configured to be optically mode matched to the photonic waveguide located on the PIC.

6. The method of claim 1, further comprising arranging the laser die on the PIC so that the output optical energy that is output from the laser die is vertically coupled to the photonic waveguide located on the PIC.

7. The method of claim 1, wherein the laser die further includes a silicon waveguide disposed on the silicon substrate, the silicon waveguide being configured to directly receive the optical energy from the semiconductor laser and couple the optical energy to the photonic waveguide located on the PIC.

8. A method of forming a semiconductor device with a photonic integrated circuit (PIC), comprising:
providing a device die that includes a semiconductor device and a silicon-based photonic waveguide disposed on a silicon substrate, the silicon-based photonic waveguide being configured to transmit optical energy to and/or receive optical energy from the semiconductor device and provide the optical energy as output energy that is output from the device die and/or receive the optical energy as input energy that is input to the device die; and
optically coupling the device die with the PIC so that the optical energy received by and/or output from the device die is coupled from and/or to a photonic waveguide located on the PIC.

9. The method of claim 8, further comprising:
forming a trench in the PIC;
arranging the device die in the trench so that the output optical energy output from the device die is laterally coupled to the photonic waveguide located on the PIC.

10. The method of claim 9, wherein the device die is arranged in the trench such that the silicon substrate is located at a greater depth in the trench than the semiconductor device.

11. The method of claim 9, wherein the device die is arranged in the trench such that the semiconductor device is located at a greater depth in the trench than the silicon substrate.

12. The method of claim 8, wherein the silicon-based photonic waveguide is configured to be optically mode matched to the photonic waveguide located on the PIC.

13. The method of claim 8, further comprising arranging the device die on the PIC so that the output optical energy that is output from the device die is vertically coupled to the photonic waveguide located on the PIC.

14. The method of claim 8, wherein the device die further includes a silicon waveguide disposed on the silicon substrate, the silicon waveguide being configured to directly receive the optical energy from the semiconductor device and couple the optical energy to the photonic waveguide located on the PIC.

15. The method of claim 8, wherein the semiconductor device is a semiconductor optical amplifier or an optical modulator.

16. A method of optically coupling a semiconductor device to and/or from a photonic integrated circuit (PIC), comprising:
providing a semiconductor device disposed on a die that is formed on a first substrate, the first substrate including one or more first silicon-based waveguides that couple light to the semiconductor device from an input waveguide of the die and/or couple light from the semiconductor device to an output waveguide of the die; and
providing a PIC disposed on a second substrate, the second substrate including one or more second silicon-based waveguides that couple light to the PIC from the output waveguide of the die and/or couple light from the PIC to the input waveguide of the die, wherein the die includes materials that are dissimilar from materials in the PIC and the first silicon-based input waveguides of the die and the second silicon-based waveguides are substantially identical.

17. An optical arrangement, comprising:
a laser die that includes a semiconductor laser and a silicon-based photonic waveguide disposed on a silicon substrate, the silicon-based photonic waveguide being configured to receive optical energy generated by the semiconductor laser and provide the optical energy as output energy that is output from the laser die; and
a photonic integrated circuit (PIC) coupled to the laser so that the optical energy output from the laser die is coupled to a photonic waveguide located on the PIC.

18. The optical arrangement of claim 17, further comprising a trench disposed in the PIC, the laser die being arranged in the trench so that the output optical energy output from the laser die is laterally coupled to the photonic waveguide located on the PIC.

19. The optical arrangement of claim 18, wherein the laser die is arranged in the trench such that the silicon substrate is located at a greater depth in the trench than the semiconductor laser.

20. The optical arrangement of claim 18, wherein the laser die is arranged in the trench such that the semiconductor laser is located at a greater depth in the trench than the silicon substrate.

21. The optical arrangement of claim 17, wherein the silicon-based photonic waveguide is configured to be optically mode matched to the photonic waveguide located on the PIC.

22. The optical arrangement of claim 17, wherein the laser die is arranged on the PIC so that the output optical energy that is output from the laser die is vertically coupled to the photonic waveguide located on the PIC.

23. The optical arrangement of claim 17, wherein the laser die further includes a silicon waveguide disposed on the silicon substrate, the silicon waveguide being configured to directly receive the optical energy from the semiconductor laser and couple the optical energy to the photonic waveguide located on the PIC.
